(19) United States
(12) Patent Application Publication
(10) Pub. No.: US 2015/0348906 A1
(43) Pub. Date: Dec. 3, 2015

(54) ELECTRONIC DEVICE PACKAGE

(71) Applicant: SAMSUNG ELECTRONICS CO., LTD., SUWON-SI (KR)

(72) Inventors: Jong Kil PARK, Suwon-si (KR); Min Young SON, Seoul (KR)

(73) Assignee: SAMSUNG ELECTRONICS CO., LTD.

(21) Appl. No.: 14/581,221

(22) Filed: Dec. 23, 2014

(30) Foreign Application Priority Data
Jun. 3, 2014 (KR) 10-2014-0067441

(51) Int. Cl. H01L 23/522; H01L 23/528

(52) U.S. Cl. CPC H01L 23/5226; H01L 23/528

(57) ABSTRACT

An electronic device package may include a package body, an electronic device, and at least one conductive via. The package body includes a first surface and a second surface opposite to the first surface. The electronic device is disposed on the first surface. The at least one conductive via extends through the package body and includes a first end located in a mounting region of the first surface corresponding to a region on which the electronic device is disposed. The first end may have a first dimension measured along a first direction greater than a second dimension measured along a second direction substantially perpendicular to the first direction.

### CROSS-REFERENCE TO RELATED APPLICATION

This application claims priority under 35 U.S.C. §119 to Korean Patent Application No. 10-2014-0067441 filed on Jun. 3, 2014, with the Korean Intellectual Property Office, the entire disclosure of which is incorporated herein by reference.

### BACKGROUND

The present disclosure relates to an electronic device package.

Electronic devices may be driven when external electrical energy is applied thereto, and include photoelectric devices, such as semiconductor light-emitting devices and solar cells. Usually, an electronic device maybe used in a package prior to being installed in an apparatus. A package substrate used in such a package may include a through-silicon via (TSV) used as an electrical connecting means. TSV technology enables signals and/or power to be transmitted between an electronic device and an external apparatus by forming a via hole passing through a package substrate so as to electrically interconnect a top and a bottom of the package substrate.

### SUMMARY

An exemplary embodiment in the present disclosure may provide an electronic device package having reduced thermal stress applied to an electronic device.

An exemplary embodiment in the present disclosure may provide an electronic device package having improved reliability.

According to an exemplary embodiment in the present disclosure, an electronic device package includes a package body, an electronic device, and at least one conductive via. The package to body includes a first surface and a second surface opposite to the first surface. The electronic device is disposed on the first surface. The at least one conductive via extends through the package body and includes a first end located in a mounting region of the first surface corresponding to a region on which the electronic device is disposed. The first end has a first dimension measured along a first direction that is greater than a second dimension measured along a second direction substantially perpendicular to the first direction.

The second dimension of the first end may be less than or equal to 0.1 times the first dimension.

The second dimension of the first end may be less than or equal to 0.3 times the first dimension.

The electronic device may include a first electrode and a second electrode, and the at least one conductive via may include a first conductive via and a second conductive via respectively electrically connected to the first electrode and the second electrode.

The first direction of the first end of the first conductive via may be the same as a first direction of a first end of the second conductive via.

On the contrary, the first direction of the first end of the first conductive via may be different from the first direction of the first end of the second conductive via.

The electronic device package may further include a first electrode pad and a second electrode pad disposed on the first surface and respectively electrically connected to the first electrode and the second electrode.

The at least one conductive via may include a plurality of first conductive vias located in the mounting region of the first surface and a plurality of second conductive vias located in the mounting region of the first surface.

The first ends of the plurality of first conductive vias may have different first dimensions.

In this case, among the plurality of first conductive vias, one first conductive via located adjacent to a central portion of the mounting region may have a greater first dimension at the first end than another first conductive via located adjacent to an outer portion of the mounting region.

In addition, the first ends of the plurality of first conductive vias may have different first directions from each other.

The first end of the at least one conductive via may include one edge and another edge opposite to the one edge in the first direction, and the one edge may have a different length from a length of the other edge.

In this case, the other edge may be disposed closer to a periphery of the mounting region than the one edge, and the one edge may be longer than the other edge.

The at least one conductive via may include a second end located on the second surface of the package body and opposite to the first surface, and may have a tapered cross-section along a plane perpendicular to the first surface from the first end to the second end.

The at least one conductive via may include a second end located on the second surface of the package body opposite to the first surface, and may have a cross-sectional area along a plane parallel to the first surface that increases from the first end to the second end.

The first end of the at least one conductive via may extend outside of the mounting region on the first surface of the package body so as to extend in an area of the first surface that is not overlapped by the electronic device.

According to another exemplary embodiment in the present disclosure, an electronic device package includes a package body, an electronic device, at least one via hole, and a conductor. The package body has a first surface and a second surface opposite to the first surface. The electronic device is disposed on the first surface. The at least one via hole extends through the package body and includes a first opening located in a mounting region of the first surface corresponding to a region on which the electronic device is disposed. The conductor extends along an inner sidewall of the at least one via hole and is electrically connected to the electronic device. The first opening has a first dimension measured along a first direction greater than a second dimension measured along a second direction substantially perpendicular to the first direction.

The conductor may extend from the inner sidewall of the at least one via hole onto the first and second surfaces of the package body so as to cover portions of the first and second surfaces located adjacent to the at least one via hole.

According to an exemplary embodiment in the present disclosure, a package substrate is provided for mounting an electronic device having a plurality of electrodes. The package substrate includes a package body, a plurality of via holes, and a plurality of via conductors. The package body has a first surface and a second surface opposite to the first surface. The via holes each extend from the first surface through the package body to the second surface. Each via conductor is disposed in a corresponding via hole of the plurality of via holes. Each via hole of the plurality of via holes has a first end located in a mounting region of the first surface corresponding to a region on which an electrode of the electronic device is mounted. The first end of each via hole has a first dimension measured along a first direction greater than a second dimension measured along a second direction substantially perpendicular to the first direction. Each via hole has a second end located in the second surface, and the second end of each via hole has a third dimension measured along the first direction greater than a fourth dimension measured along the second direction substantially perpendicular to the first direction.

The first end of each via hole may be vertically aligned through a thickness of the package body with the second end of the via hole. The first, second, third, and fourth dimensions may be different from each other.

According to an exemplary embodiment in the present disclosure, an electronic device package includes a package body including a first surface on which an electronic device is disposed and a second surface opposite to the first surface. At least one conductive via includes a first end located on the first surface in a mounting region on which the electronic device is disposed, and passes through the first surface and the second surface of the package body. The first end has a first dimension measured along a first direction greater than a second dimension measured along a second direction substantially perpendicular to the first direction.

According to an exemplary embodiment in the present disclosure, an electronic device package includes a package body including a first surface on which an electronic device is disposed and a second surface opposite to the first surface. At least one via hole includes a first opening located in the first surface in a mounting region defined as a region on which the electronic device is disposed. The at least one via hole passes through the first surface and the second surface of the package body, and a conductor extends along an inner sidewall of the at least one via hole and electrically connects to the electronic device. The first opening has a first dimension in a first direction greater than a second dimension in a second direction substantially perpendicular to the first direction.

### BRIEF DESCRIPTION OF DRAWINGS

The above and other aspects, features and other advantages in the present disclosure will be more clearly understood from the following detailed description taken in conjunction with the accompanying drawings, in which:

FIG. 1 is a partially cutaway perspective view schematically illustrating an electronic device package according to an exemplary embodiment in the present disclosure;

FIGS. 2A and 2B are respectively a top view and a bottom view of a package substrate in the electronic device package of FIG. 1;

FIG. 3A is a cross-sectional view taken along line I-I′ of the electronic device package in FIG. 1, and FIG. 3B is a cross-sectional view illustrating an embodiment modified from that illustrated in FIG. 3A;

FIGS. 4, 5A, 5B, and 6 to 8 are top views of a package substrate illustrating electric device packages of various embodiments modified from that illustrated in FIG. 2A;

FIGS. 9 and 10 are cross-sectional views schematically illustrating electronic device packages according to exemplary embodiments in the present disclosure;

FIGS. 11A, 11B, and 12 illustrate an electronic device package according to an exemplary embodiment in the present disclosure;

FIGS. 13 to 15, 16A, 16B, and 17 to 21 are diagrams schematically illustrating main process steps of a method of fabricating an electronic device package according to an exemplary embodiment in the present disclosure;

FIGS. 22A to 22C are diagrams schematically illustrating main process steps of a method of fabricating an electronic device package according to a modified exemplary embodiment from that described with reference to FIGS. 13 to 15, 16A, 16B, and 17 to 21;

FIG. 23 is a plot comparing experimental measurements obtained in different electronic device packages according to an exemplary embodiment in the present disclosure;

FIGS. 24 and 25 are exploded perspective views illustrating example apparatuses in which an electronic device package according to an exemplary embodiment in the present disclosure is applied as a light source of a lighting apparatus;

FIGS. 26 and 27 are cross-sectional views illustrating example units in which an electronic device package according to an exemplary embodiment in the present disclosure is applied as a light source of a backlight unit; and

FIG. 28 is a cross-sectional view illustrating an example lamp in which an electronic device package according to an exemplary embodiment in the present disclosure is applied as a light source of a head lamp.

### DETAILED DESCRIPTION

Hereinafter, embodiments in the present disclosure will be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art. In the drawings, the shapes and dimensions of elements may be exaggerated for clarity, and the same reference numerals will be used throughout to designate the same or like elements. Throughout this disclosure, directional terms such as “upper,” “upper (portion),” “upper surface,” “lower,” “lower (portion),” “lower surface,” or “side surface” may be used to describe the relationship of one element or feature to another, as illustrated in the drawings. It is understood that such descriptions refer to the relative positions of the elements or features and are intended to encompass different orientations in use or operation than the particular orientations depicted in the drawings.

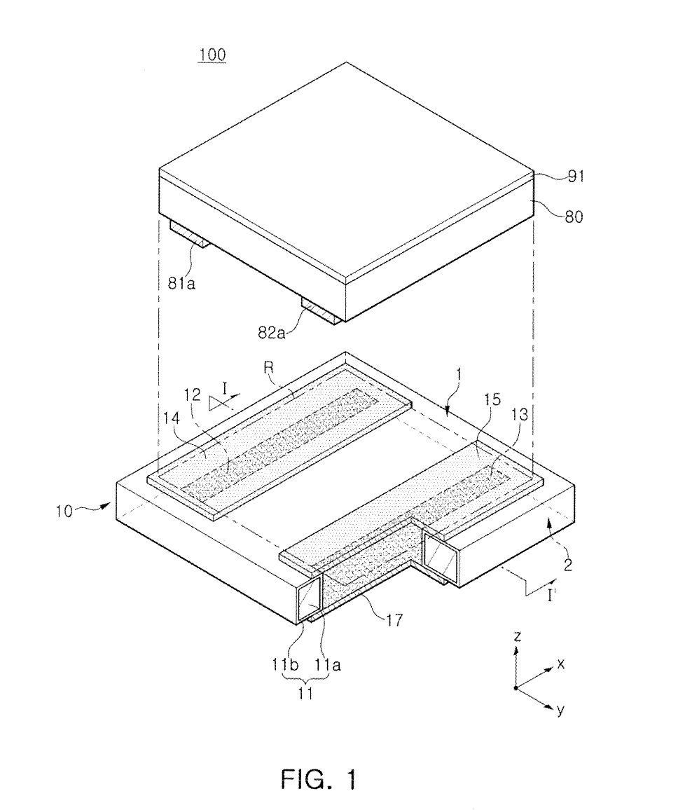

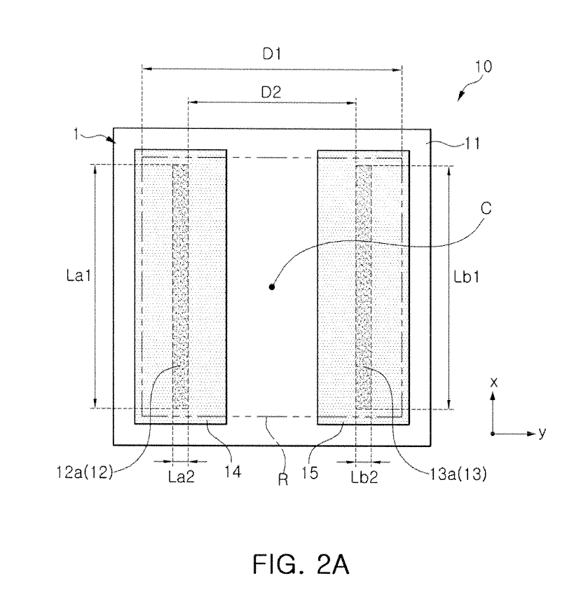

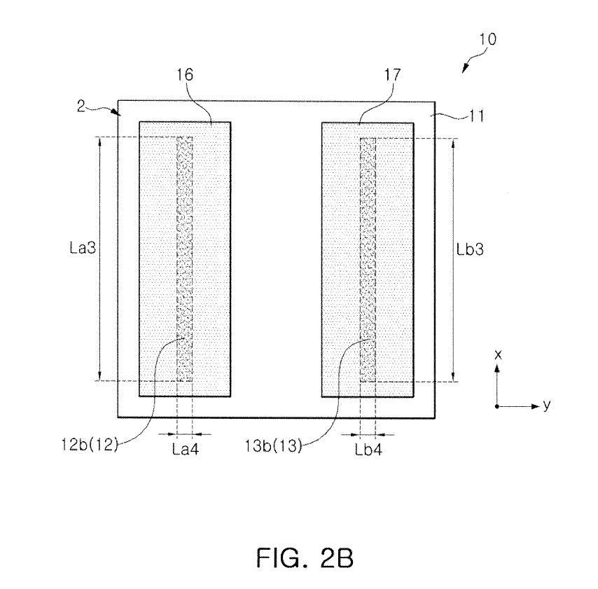

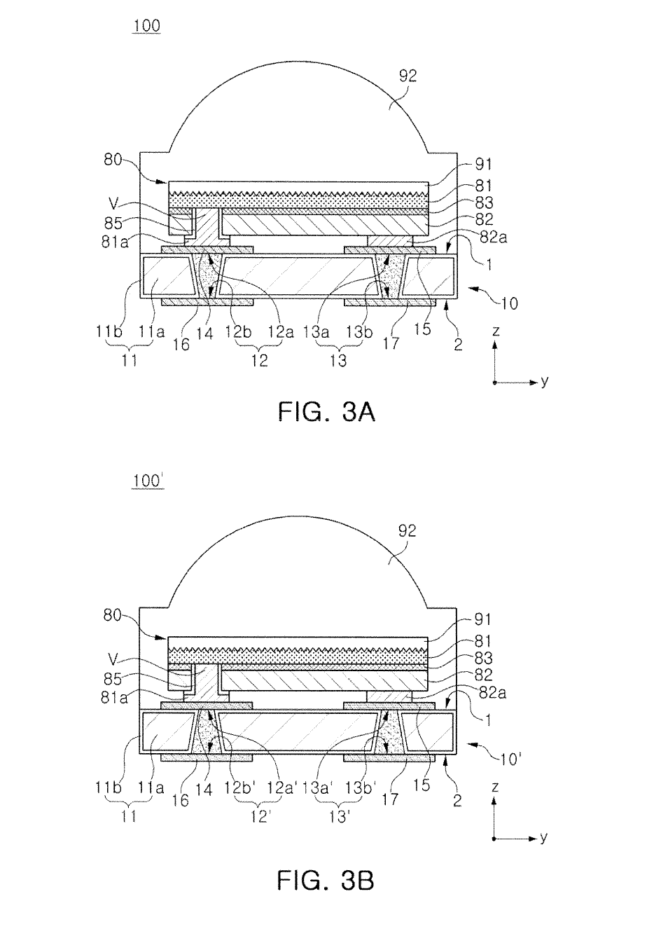

FIGS. 1, 2A, 2B, and 3A are views illustrating an electronic device package according to an exemplary embodiment in the present disclosure. FIG. 1 is a partially cutaway perspective view schematically illustrating an electronic device package according to an exemplary embodiment in the present disclosure, and FIGS. 2A and 2B are respectively a top view and a bottom view of a package substrate in the electronic device package of FIG. 1. FIG. 3A is a cross-sectional view taken along line I-I′ of the electronic device package in FIG. 1. In FIG. 1, a lens part (among the components illustrated in FIG. 3A) is omitted for ease of illustration.

The electronic device package according to an exemplary embodiment in the present disclosure may include an optoelectronic device package, such as a semiconductor light-emitting device package or a solar cell package, a memory device package, or a logic device package.

Referring to FIGS. 1, 2A, 2B, and 3A, an electronic device package 100 according to an exemplary embodiment may include a package substrate 10 and an electronic device 80. The package substrate 10 may include a package body 11 having a first (upper) surface 1 and a second (lower) surface 2 opposite to the first surface 1, and one or more conductive vias 12 and 13 passing or extending through the package body 11 from the first surface 1 to the second surface 2. In this case, the electronic device 80 may be disposed on the first surface 1 of the package body 11.

In this exemplary embodiment, the electronic device 80 may be, for example, a semiconductor light-emitting device. In this case, the electronic device package 100 maybe a semiconductor light-emitting device package, for example, a chip scale package (CSP) and, more specifically, a wafer level package (WLP).

The package body 11 may include a body portion 11a and an insulating layer 11b surrounding the body portion 11a.

The body portion 11a may include a conductive or insulating material, for example, a semiconductor material such as silicon (Si), a ceramic material such as AlN and Al₂O₃, a metal material, or a polymer material.

The insulating layer 11b may cover at least one surface of the body portion 11a. The insulating layer 11b may be formed of an electrically insulating material, for example, a resin. When the body portion 11a is formed of an insulating material, the insulating layer 11b may be omitted.

The package substrate 10 may further include an electrode pad disposed on the first surface 1 of the package body 11. In this exemplary embodiment, the electrode pad may be formed of first and second electrode pads 14 and 15 respectively corresponding to and electrically connected to first and second electrodes 81a and 82a included in the electronic device 80. The first and second electrode pads 14 and 15 may be formed in the form of a thin film of an electrically conductive material, such as copper and/or silver, using an electroplating or deposition process, but are not limited thereto.

In addition, in this exemplary embodiment, the package substrate 10 may further include an external terminal disposed on the second surface 2 of the package body 11. The external terminal may include first and second external terminals 16 and 17 disposed on the second surface 2 and respectively corresponding to and electrically connected to the first and second electrode pads 14 and 15. The external terminal may receive an external electric signal for driving the electronic device 80. The first and second external terminals 16 and 17 may be formed of the same material as the first and second electrode pads 14 and 15, but are not limited thereto. The first and second external terminals 16 and 17 are not particularly limited as long as they are formed of electrically conductive materials.

The electronic device 80 may perform a predetermined function when an electric signal is applied thereto, and may be disposed on the first surface 1 of the package body 11. A portion of the first surface 1 in which the electronic device 80 is disposed may be defined as a mounting region R.

The electronic device 80 may include, for example, a semiconductor light-emitting device. Hereinafter, the semiconductor light-emitting device is assumed as being used as the electronic device 80 according to the exemplary embodiment in the present disclosure. In this case, the electronic device 80 may include a light-emitting structure formed of a first conductivity-type semiconductor layer 81, an active layer 83, and a second conductivity-type semiconductor layer 82, and first and second electrodes 81a and 82a.

In more detail, with reference to FIG. 3a, the first and second conductivity-type semiconductor layers 81 and 82 may be respectively an n-type semiconductor layer and a p-type semiconductor layer, but are not limited thereof. Conversely, the first and second conductivity-type semiconductor layers 81 and 82 may be respectively p-type and n-type semiconductor layers. The first and second conductivity-type semiconductor layers 81 and 82 may be a nitride semiconductor, for example, a material having a composition of AlₓIn_{y}Ga_{1-x-y}N (0≦x≦1, 0≦y≦1, and 0≦x+y≦1), and each layer is formed of a single layer or a plurality of layers having different characteristics, such as different doping concentrations and different compositions from each other. However, the first and second conductivity-type semiconductor layers 81 and 82 may use an AlInGaP-based or AlInGaAs-based semiconductor beside the nitride semiconductor.

The active layer 83 may be disposed between the first and second conductivity-type semiconductor layers 81 and 82, and may emit light having a predetermined amount of energy by electron-hole recombination. The active layer 83 may have a multi-quantum well (MQW) structure in which quantum well layers and quantum barrier layers are alternately stacked. For example, when the active layer 83 is a nitride semiconductor, a GaN/InGaN structure maybe used. However, the active layer 83 is not limited thereto, and a single-quantum well (SQW) structure may be used.

In addition, although not shown in FIG. 3A, the electronic device 80 may further include a growth substrate disposed on the first conductivity-type semiconductor layer 81. The growth substrate may include a textured structure formed on a surface on which the first conductivity-type semiconductor layer 81 is not formed. The growth substrate may be removed by performing, for example, a laser lift-off process. In addition, although not shown in FIG. 3A, a passivation layer may be formed to cover at least a part of upper and side surfaces of the electronic device 80. The passivation layer may be silicon nitride or silicon oxide.

The first conductivity-type semiconductor layer 81 may have a textured structure on a surface thereof, by which light extraction efficiency may be further improved. For example, the textured structure maybe obtained by removing the growth substrate from the light-emitting structure and then wet-etching the first conductivity-type semiconductor layer 81 or dry-etching it using plasma.

The first and second electrodes 81a and 82a may be located on a lower surface of the electronic device 80. The first and second electrodes 81a and 82a may be respectively disposed on the first and second electrode pads 14 and 15 and electrically connected thereto, as shown in FIGS. 1 and 3A.

The first and second electrodes 81a and 82a may be formed of a conductive material well-known in the art, for example, one or more of Ag, Al, Ni, Cr, Cu, Au, Pd, Pt, Sn, W, Rh, Ir, Ru, Mg, Zn, Ti, and/or alloys thereof. In this exemplary embodiment, the first electrode 81a may include a via V passing through the second conductivity-type semiconductor layer 82 and the active layer 83 to be electrically connected to the first conductivity-type semiconductor layer 81. An electrode isolating layer 85 electrically insulating the first electrode 81a from the second conductivity-type semiconductor layer 82 and the active layer 83 may be disposed around the via V. A plurality of vias V may be formed, and arranged, for example, in rows and columns.

The package substrate 10 may include one or more conductive vias passing through the package body 11.

The conductive vias may include an electrically conductive material, for example, a metal such as Cu, Al, Au, Ag, Ni, or Pd, and pass through the package body 11 from the first surface 1 to the second surface 2 to electrically connect the electrode pads 14 and 15 disposed on the first surface to the external terminal 16 and 17 disposed on the second surface 2. More specifically, the conductive vias according to the exemplary embodiment in the present disclosure may include first and second conductive vias 12 and 13, and may be electrically connected to the first and second electrodes 81a and 82a of the electronic device 80 through the first and second electrode pads 14 and 15, respectively.

The first and second conductive vias 12 and 13 may include respective first ends 12a and 13a and respective second ends 12b and 13b. In this specification, the first ends 12a and 13a may be defined as ends disposed on (or coplanar with) the first surface 1 of the package body 11 and perpendicular to the direction of the thickness z of the conductive vias 12 and 13. Similarly, the second ends 12b and 13b may be defined as ends disposed on (or coplanar with) the second surface 2 of the package body 11 and perpendicular to the direction of the thickness z of the conductive vias 12 and 13.

The first ends 12a and 13a may be disposed on (or coplanar with) the first surface 1 of the package body 11, and have first dimensions La1 and Lb1 in a first direction x greater than second dimensions La2 and Lb2 in a second direction y substantially perpendicular to the first direction x, as illustrated in FIGS. 1 and 2A (that is, La1>La2 and Lb1>Lb2). The first ends 12a and 13a may have a rectangular shape in a plan view of the package substrate 10 as shown in FIGS. 1 and 2A, but is not limited thereto.

Alternatively, the first ends 12a and 13a may have an elliptical shape having a major axis and a minor axis.

The second ends 12b and 13b may be disposed on (or coplanar with) the second surface 2 of the package body 11, as illustrated in FIG. 2B, and formed on an opposing end to the first ends 12a and 13a in the conductive vias 12 and 13. The second ends 12b and 13b may have third dimensions La3 and Lb3 in the first direction x greater than fourth dimensions La4 and Lb4 in the second direction y substantially perpendicular to the first direction x, similarly to the first ends 12a and 13a (that is, La3>La4 and Lb3>Lb4).

Although not limited thereto, the conductive vias 12 and 13 according to the exemplary embodiment in the present disclosure may be provided in the form of a conductive portion formed of an electrically conductive material filling a via hole passing through the package body 11 and including first and second openings respectively formed on the first and second surfaces 1 and 2. Here, the via hole may be formed using an etching process such as dry-etching and/or wet-etching, or a laser drilling process.

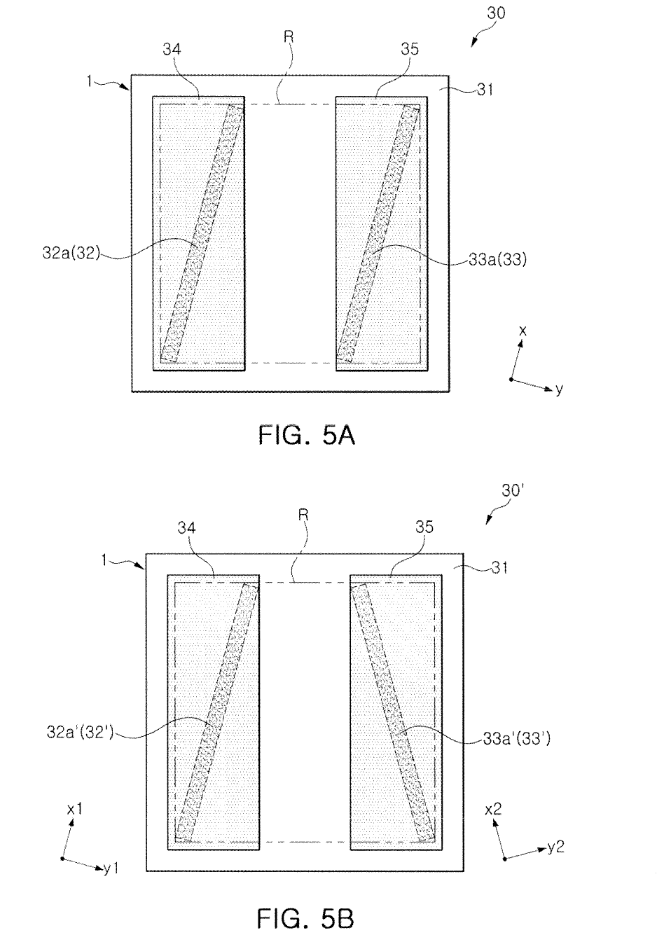

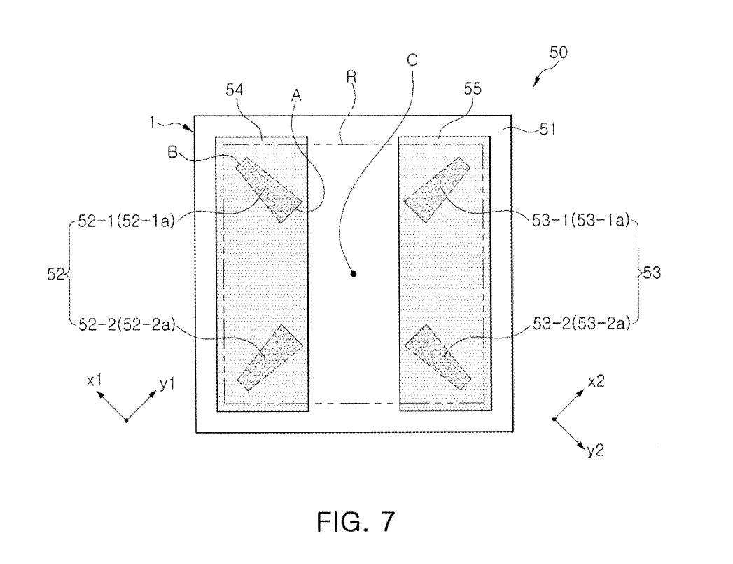

The first direction x of the first ends 12a and 13a and the first direction x of the second ends 12b and 13b, which are included in the conductive vias 12 and 13, may be the same direction. In addition, the first direction x of the first end 12a included in the first conductive via 12 may be the same direction as the first direction x of the first end 13a included in the second conductive via 13, but is not limited thereto. For example, as will be illustrated in FIGS. 5B and 7, a first direction of the first end 12a included in the first conductive via 12 may be a different direction from a first direction of the first end 13a included in the second conductive via 13.

The first ends 12a and 13a may be disposed in the mounting region R, defined as a region in which the electronic device 80 is located on the first surface 1 of the package body 11. When the conductive via is formed of the first and second conductive vias 12 and 13 as described in this exemplary embodiment, a distance D2 between the first and second conductive vias 12 and 13 may be smaller than a horizontal dimension D1 of the mounting region R, that is, a horizontal dimension of the electronic device 80.

Thus, since the conductive vias 12 and 13 are disposed in the mounting region R, the first ends 12a and 13a of the conductive vias 12 and 13 may be disposed in an area overlapped by the electronic device 80 in the direction of the thickness of the electronic device package 100. Accordingly, the conductive vias 12 and 13 may have a heat dissipation effect so that heat generated in the electronic device 80 is effectively dissipated to the outside of the device. In particular, since the first ends 12a and 13a of the conductive vias 12 and 13 are formed in a rectangular shape, the first ends 12a and 13a may have a greater area in contact with the electrode pads 14 and 15 or the electronic device 80 and a smaller thermal resistance than a conductive via having a cylindrical shape having a constant radius of bottom surface thereof. For example, when the electronic device 80 is a semiconductor light-emitting device, thermal stress applied on a semiconductor layer of the semiconductor light-emitting device may be reduced, light-emitting efficiency may be increased, and uniformly distributed current may be effectively supplied to the first and second electrodes 81a and 82a of electronic device 80. In addition, reliability of electric connection by the conductive vias 12 and 13 may be increased.

As illustrated in FIG. 3A, a cross-sectional area of the conductive vias 12 and 13 (measured in the x-y plane) may decrease from the first ends 12a and 13a toward the second ends 12b and 13b. Such a structure may be implemented in such a manner that etching is applied from the first surface 1 of the package body 11 toward the second surface 2 of the package body 11 when forming the via hole passing through the package body 11 for forming the conductive vias 12 and 13. In this case, since the first and second dimensions La1, La2, Lb1, and Lb2 of the first ends 12a and 13a adjacently to the electronic device 80 are greater than the third and fourth dimensions La3, La4, Lb3, and Lb4 of the second ends 12b and 13b in the conductive vias 12 and 13 (that is, La1>La3, La2>La4, Lb1>Lb3, and Lb2>Lb4), the conductive vias 12 and 13 may be advantageous for heat dissipation, but are not limited thereto.

For example, in a case of an electronic device package 100 according to an exemplary embodiment in the present disclosure, conductive vias 12′ and 13′ formed on a package substrate 10′ may have a cross-sectional area decreasing from second ends 12b′ and 13b′ toward first ends 12a′ and 13a′, as illustrated in FIG. 3B. Alternatively, the conductive vias 12 and 13 may pass through the package substrate 10 from the first surface 1 to the second surface 2 with constant cross-sectional areas.

In these exemplary embodiments, the electronic device package 100 may further include a wavelength converting part 91 and a lens part 92.

The wavelength converting part 91 may include a fluorescent material, excited by light emitted by the electronic device 80 and emitting light of a different wavelength. The light emitted by the fluorescent material and the light emitted by the electronic device 80 may combine to allow a preferred light such as white light to be obtained. The wavelength converting part 91 is illustrated as being disposed on the electronic device 80 in the form of a thin film, but is not limited thereto. For example, the wavelength converting part 91 may be disposed in the lens part 92 to be spaced apart from the electronic device 80 by a predetermined distance.

The lens part 92 may cover and encapsulate the electronic device 80. The lens part 92 may be formed of a material having high light-transmittance and high thermal resistance, for example, silicone, epoxy, glass, and/or plastic. The lens part 92 may have a convex or concave lens structure by which an orientation angle of light emitted through an upper surface of the lens part 92 can be controlled. The lens part 92 may be formed of a resin with high transparency so that light generated by the light-emitting structure is passed therethrough with minimal loss. For example, the lens part 92 may be formed of an elastic resin, silicone, epoxy resin, or plastic.

In this exemplary embodiment, the lens part 92 may have a dome shape having a convex upper surface as illustrated in FIGS. 3A and 3B, but is not limited thereto. For example, the lens part 92 may include colloidal particles on a surface thereof in order to improve spread of light in a lighting apparatus or a backlight unit, or have a flat upper surface. Further, the lens part 92 may have an aspheric surface and/or an asymmetric shape, or a textured structure on the upper surface thereof. In addition, the lens part 92 may include a Fresnel-shaped light-collecting unit in order to improve linearity of light in a camera flash or the like, or have a textured structure on the upper surface thereof.

The electronic device package according to the exemplary embodiment in the present disclosure may reduce thermal stress on the electronic device thereinside and ensure reliability.

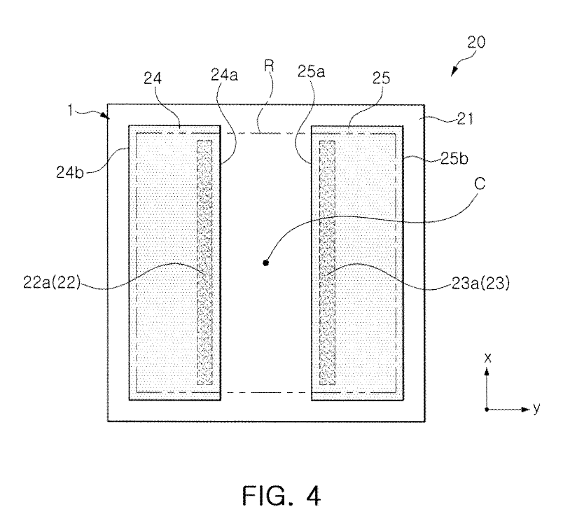

FIG. 4 is a top view of a package substrate 20 illustrating an electronic device package modified from that in the exemplary embodiments of FIGS. 1, 2A, 2B, and 3A. Hereinafter, descriptions of the same parts as those in the above-described embodiments are omitted, and the description will focus on those parts that are different from corresponding parts of the embodiments described above.

As illustrated in FIG. 4, the first and second conductive vias 22 and 23 may respectively include first ends 22a and 23a having a first dimension and a second dimension smaller than the first dimension, and the first ends 22a and 23a may be disposed a mounting region R on a first surface 1 of a package body 21.

In this exemplary embodiment, first and second electrode pads 24 and 25 may be disposed on the first surface 1 of the package body 21. The first and second electrode pads 24 and 25 may include first sides 24a and 25a disposed to face each other, and second sides 24b and 25b respectively opposing the first sides 24a and 25a. The first ends 22a and 23a of the first and second conductive vias 22 and 23 are respectively disposed to be adjacent to the first sides 24a and 25a of the first and second electrode pads 24 and 25.

More specifically, the first end 22a of the first conductive via 22 may be disposed to be closer to the first side 24a than to the second side 24b of the first electrode pad 24, and the first end 23a of the second conductive via 23 may be disposed to be closer to the first side 25a than to the second side 25b of the second electrode pad 25.

In this case, since each of the first ends 22a and 23a of the first and second conductive vias 22 and 23 is disposed adjacent to (or in close proximity to) the center C of the mounting region R, that is, adjacent to a central portion of the electronic device 80 where a large amount of heat is generated, the heat dissipating performance may be more effectively improved.

Here, the second ends of the conductive vias 22 and 23 may have a similar shape to the first ends 22a and 23a illustrated in FIG. 4. In addition, the second ends of the conductive vias 22 and 23 may be formed on the second surface 2 of the package body 21 at a position corresponding to the first ends 22a and 23a disposed on the first surface 1 of the package body 21 (e.g., a position vertically below the position of the first ends 22a and 23a along the z dimension). This vertical alignment of the first and second ends may be applied to exemplary embodiments which will be described later as well.

FIGS. 5A and 5B are top views of package substrates 30 and 30′ illustrating electronic device packages modified from those shown in the exemplary embodiments of FIGS. 1, 2A, 2B, and 3A.

Referring to FIG. 5A, a package substrate 30 may include a package body 31 and one or more conductive vias 32 and 33. First ends 32a and 33a of the conductive vias 32 and 33 according to an exemplary embodiment in the present disclosure may be disposed in an area overlapped by electrode pads 34 and 35 in a thickness direction of the electronic device package. The first ends 32a and 33a may each have a first dimension in a first direction, and a second dimension in a second direction substantially perpendicular to the first direction. Here, the first direction may be a diagonal direction of the electrode pads 34 and 35 in a plan view of the package substrate 30.

More specifically, as illustrated in FIG. 5A, the first direction of the first end 32a of the first conductive via 32 may be a direction from one vertex of the first electrode pad 34, at which a side of the first electrode pad 34 meets another side thereof, to another vertex of the first electrode pad 34 diagonally opposite to the one vertex. Similarly, the first direction of the first end 33a of the second conductive via 33 may be a direction from one vertex of the second electrode pad 35, at which a side of the second electrode pad 35 meets another side thereof, to another vertex of the second electrode pad 35 diagonally opposite to the one vertex.

For example, in the electrode pads 34 and 35 having a rectangular shape in a plan view of the package substrate 30, the first ends 32a and 33a of the conductive vias 32 and 33 may be understood as each having a first direction aligned with a diagonal direction of the rectangular shape of the corresponding electrode pad 34 or 35.

In this case, the first ends 32a and 33a may be disposed in a mounting region R to effectively transmit heat generated from the electronic device 80 to the outside. Further, since the first dimension of each of the first ends 32a and 33a is longer than the first dimension of the first ends in the previously described embodiment, the heat dissipating performance may be more effective.

Meanwhile, the first ends 32a and 33a of the first and second conductive vias 32 and 33 in FIG. 5A are illustrated as having the same first direction x as each other, but are not limited thereto. Accordingly, as illustrated in FIG. 5B, first and second conductive vias 32′ and 33′ of a package substrate 30′ may include first ends 32a′ and 33a′, and a first direction xl of the first end 32a′ of the first conductive via 32′ maybe different from a first direction x2 of the first end 33a′ of the second conductive via 33′.

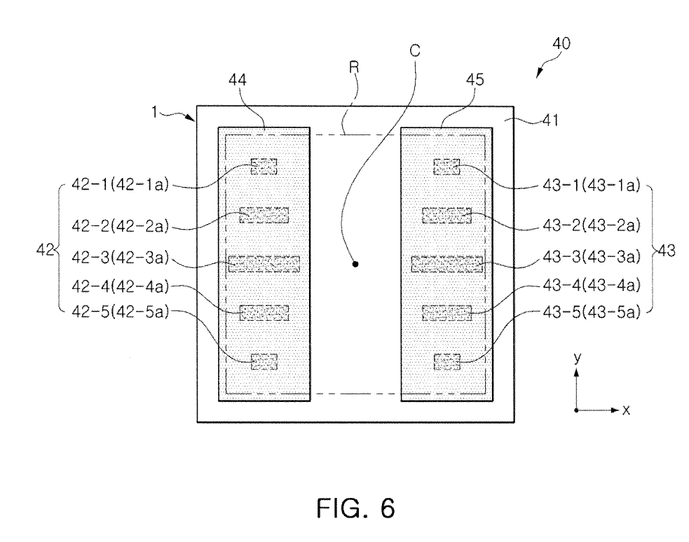

FIG. 6 is a top view of a package substrate 40 for illustrating an electronic device package modified from that in the exemplary embodiments of FIGS. 1, 2A, 2B, and 3A.

Referring to FIG. 6, the package substrate 40 may include a package body 41, first and second electrode pads 44 and 45, and first and second conductive vias 42 and 43. In this exemplary embodiment, a plurality of first and second conductive vias 42 and 43 may be formed. Here, the plurality of first conductive vias 42 and the plurality of second conductive vias 43 are illustrated as each respectively having five distinct vias (respectively 42-1 to 42-5 and 43-1 to 43-5), but are not limited thereto. The number of first conductive vias 42 may be different from the number of second conductive vias 43.

In this case, by disposing the plurality of first and second conductive vias 42 and 43 in the package body 41, reliability in electrical connection may be improved and heat generated from the electric device may be effectively released to the outside. In addition, more uniform currents may be provided to the electric device.

Each of the plurality of first and second conductive vias 42 and 43 may include first ends 42-1a to 42-5a and 43-1a to 43-5a, and the first ends 42-1a to 42-5a and 43-1a to 43-5a may each have a first dimension in a first direction x, and a second dimension in a second direction y substantially perpendicular to the first direction x. In this case, as illustrated in FIG. 6, the first dimension may be greater than the second dimension.

Although not shown in FIG. 6, second ends of the vias 42 and 43 may have a similar shape to the first ends 42-1a to 42-5a and 43-1a to 43-5a. The second ends may be disposed at positions on a second surface of the package body 41 corresponding to positions of the first ends 42-1a to 42-5a and 43-1a to 43-5a (e.g., at positions vertically aligned along the z dimension with positions of the first ends).

In this exemplary embodiment, at least one of the plurality of first conductive vias 42 may have a first dimension different from first dimensions of the first ends of the other conductive vias 42. For example, a first conductive via 42-3 disposed adjacent to a center portion of the mounting region R may have a greater first dimension of the first end 42-3a than those of the first conductive vias 42-1 and 42-5 disposed adjacent to outer regions of the mounting region R. Similarly, a second conductive via 43-3 disposed adjacent to a center portion of the mounting region R may have a greater first dimension of the first end 43-3a than those of the second conductive vias 43-1 and 43-5 disposed adjacent to outer regions of the mounting region R.

In this case, since the first ends 42-3a and 43-3a of the conductive vias 42-3 and 43-3 disposed adjacent to the center C of the mounting region R, that is, the center portion of the electronic device 80 where a large amount of heat is generated, are formed to be long, heat generated from the electric device may be more effectively released to the outside.

FIG. 7 is a top view of a package substrate 50 illustrating an electronic device package modified from those in the exemplary embodiments of FIGS. 1, 2A, 2B, and 3A.

Referring to FIG. 7, the package substrate 50 may include a package body 51, first and second electrode pads 54 and 55, and first and second conductive vias 52 and 53. In this exemplary embodiment, a plurality of first and second conductive vias 52 and 53 may be formed.

First directions of first ends 52-1a and 52-2a of the plurality of first conductive vias 52 may be different from each other. For example, as illustrated in FIG. 7, a first conductive via 52-1 of one of the plurality of first conductive vias 52 may have a first direction of the first end 52-1a in an x1 direction, and another first conductive via 52-2 may have a first direction of the first end 52-2a in an x2 direction. Similarly, a second conductive via 53-1 of one of the plurality of second conductive vias 53 may have a first direction of a first end 53-1a in an x2 direction, and another second conductive via 53-2 may have a first direction of a first end 53-2a in an xl direction.

In addition, the first end of the conductive via according to an exemplary embodiment in the present disclosure may include one edge and the other edge facing and opposite to the one edge in the first direction (x1 or x2), and a length of the one edge may be different from a length of the other edge. For example, as illustrated in FIG. 7, each of the first ends 52-1a, 52-2a, 53-1a, and 53-2a of the plurality of first and second conductive vias 52 and 53 may include one edge A and another edge B having a different length from the length of the one edge A. Here, the other edge B may be disposed closer to the outer periphery of the mounting region R than the one edge A, and the length of the one edge A may be greater than the length of the other edge B. In this case, since the one edge A disposed adjacent to a central portion C of the mounting region among the first ends 52-1a, 52-2a, 53-1a, and 53-2a is longer than the other edge B opposite to the one edge A, heat generated from the electronic device 80 may be effectively released outwardly.

Although second ends of the plurality of first and second conductive vias 52 and 53 are not illustrated in FIG. 7, the second ends may have a similar shape to the first ends 52-1a, 52-2a, 53-1a, and 53-2a and may be disposed on the second surface of the package body 51 in positions corresponding to the first ends 52-1a, 52-2a, 53-1a, and 53-2a.

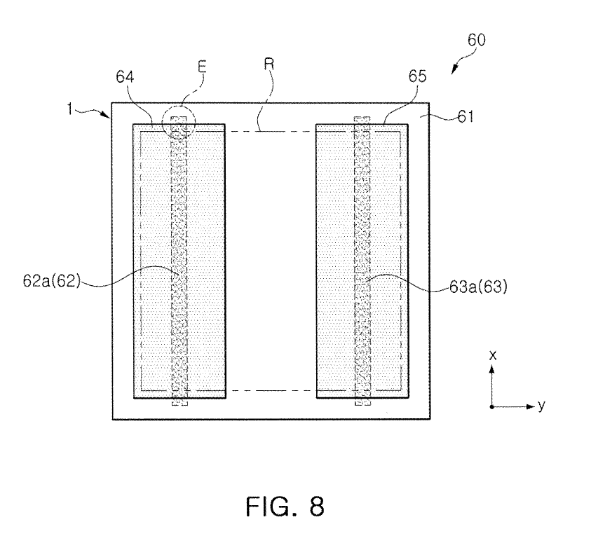

FIG. 8 is a top view of a package substrate 60 illustrating an electronic device package modified from those in the exemplary embodiments of FIGS. 1, 2A, 2B, and 3A.

Referring to FIG. 8, the package substrate 60 may include a package body 61, first and second electrode pads 64 and 65, and first and second conductive vias 62 and 63.

In the above-described embodiment, the first ends of the conductive vias are illustrated as being disposed within a region overlapped by the electronic device in a thickness direction of the electronic device package, that is, the mounting region R, but is not limited thereto.

For example, as illustrated in FIG. 8, each of first ends 62a and 63a of the first and second conductive vias 62 and 63 may be disposed to have a first dimension and a second dimension in the mounting region R, and further include an extension E extending outside of the mounting region R in an area that is not overlapped by the mounting region R. As illustrated in FIG. 8, the extensions E of the first ends 62a and 63a of the first and second conductive vias 62 and 63 may be disposed so as to extend to the outside of a region on which the first and second electrode pads 64 and 65 are disposed, in a thickness direction of the electronic device package.

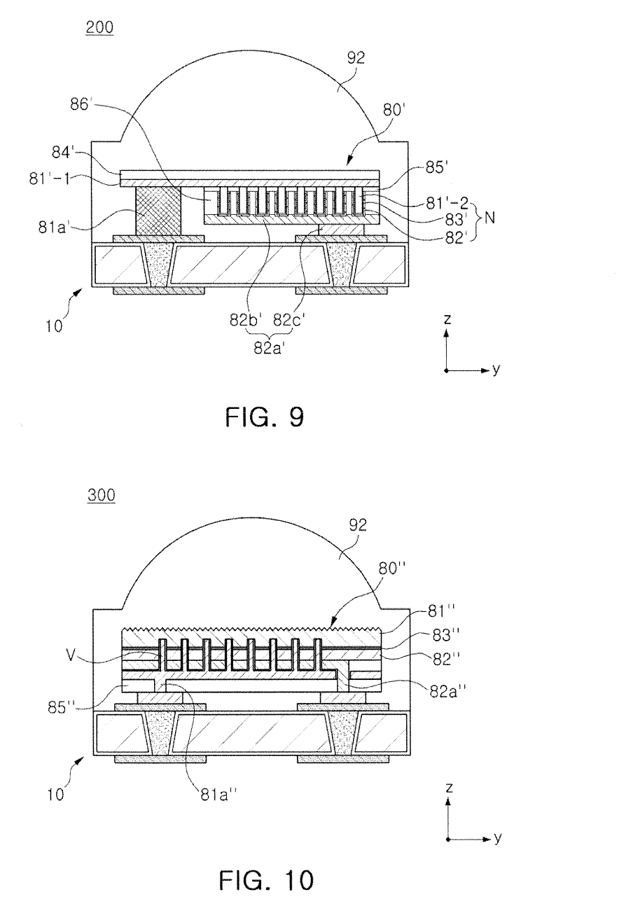

FIGS. 9 and 10 are cross-sectional views schematically illustrating electronic device packages according to exemplary embodiments in the present disclosure.

Referring to FIG. 9, an electronic device package 200 includes a package substrate 10 and an electronic device 80′. The electronic device 80′ according to the exemplary embodiment in the present disclosure may be a semiconductor light-emitting device and include a nano light-emitting structure N.

The electronic device 80′ may further include a substrate 84′, a first conductivity-type semiconductor base layer 81′-1 formed on the substrate 84′, an insulating layer 85′, and first and second electrodes 81a′ and 82a′. The nano light-emitting to structure N includes a first conductivity-type semiconductor core 81′-2 grown from the first conductivity-type semiconductor base layer 81′-1, an active layer 83′, and a second conductivity-type semiconductor layer 82′.

The substrate 84′ maybe provided as a growth substrate for nano light-emitting structure N. The substrate 84′ may include sapphire, SiC, Si, MgAl₂O₄, MgO, LiAlO₂, LiGaO₂, GaN, or the like, and an insulating material, a conductive material, or single-crystal or poly-crystal material. Sapphire is widely used as a nitride semiconductor growth substrate, is a crystal having Hexa-Rhombo R3c symmetry, has a c-axis lattice constant of 13.001 Å and an a-axis constant of 4.758 Å, and has a C(0001) plane, an A(11-20) plane, and an R(1-102) plane. In this case, since it is relatively easy to grow a nitride thin film that is stable at high temperature on the C(0001) plane, the C(0001) plane is mainly used as the nitride semiconductor growth substrate. Meanwhile, a silicon (Si) substrate may be another material suitable for the substrate 84′. By using a Si substrate suitable for being fabricated so as to have large size and having relatively low price, mass productivity may be improved. When using a Si substrate, after a nucleation layer formed of a material such as AlₓGa₁₋ₓN is formed on the substrate, a preferred structure of nitride semiconductor may be grown thereon.

The nano light-emitting structure N may include a first conductivity-type semiconductor core 81′-2, an active layer 83′, and a second conductivity-type semiconductor layer 82′. As illustrated in FIG. 9, the electronic device 80′ may include a plurality of nano light-emitting structures N formed on the substrate 84′. The nano light-emitting structure N may have a core-shell structure, for example, a rod structure, but is not is limited thereto. The nano light-emitting structure may have another structure such as a pyramid structure. For example, in some embodiments, the nano light-emitting structure N may include a nano wire, a quantum dot, or a nano box structure. In other embodiments, the nano light-emitting structure N may have a structure having an inclined surface with respect to a surface of the substrate, and a cross-sectional area parallel to the substrate 84′ may have a variety of shapes, such as a triangle, a square, a pentagon, a hexagon, an octagon, a polygon or a circle.

The first conductivity-type semiconductor base layer 81′-1 may provide a surface for growing the nano light-emitting structure N. The insulating layer 85′ may provide an open area for growing the nano light-emitting structure N, and may be a dielectric material, such as SiO₂ or SiNₓ.

The electronic device 80′ may further include a filler 86′ filling gaps between protrusions in the nano light-emitting structure N. The filler 86′ may structurally stabilize the nano light-emitting structure N, and may function to transmit or reflect light. When the filler 86′ includes a light-transmitting material, the filler 86′ may be formed of a transparent material, such as SiO₂, SiNx, an elastic resin, silicone, epoxy resin, a polymer, or plastic. When the filler 86′ includes a reflective material, the filler 86′ may include a material formed of a polymer material such as polyphthalamide (PPA) containing TiO₂ or Al₂O₃ with high light reflectance, and may be formed of a material having excellent heat resistance and light fastness.

The first and second electrodes 81a′ and 82a′ may be disposed on a lower surface of the electronic device 80′. The first electrode 81a′ may be disposed on an exposed surface of the first conductivity-type semiconductor base layer 81′-1, and the second electrode 82a′ may include an ohmic contact layer 82b′ and an electrode extension 82c′ formed under the nano light-emitting structure N and the filler 86′. In some embodiments, the ohmic contact layer 82b′ and the electrode extension 82c′ may be integrated. The ohmic contact layer 82b′ may include a reflective material. The reflective material may include Ag, Al, or an alloy containing at least one of Ag and Al. The ohmic contact layer 82b′ may be formed of a multilayered structure of the reflective or a transmissive material. Alternatively, a reflective structure using a distributed Bragg reflector (DBR) structure may be provided.

In addition, in some embodiments, the substrate 84′ may be removed and a textured structure or wavelength conversion layer may be formed on a surface of the first conductivity-type semiconductor base layer 81′-1.

Referring to FIG. 10, an electronic device package 300 to according to an exemplary embodiment in the present disclosure may include a package substrate 10 and an electronic device 80″.

The electronic device 80″ according to the exemplary embodiment in the present disclosure may be a semiconductor light-emitting device, and include a first conductivity-type semiconductor layer 81″, an active layer 83″, a second conductivity-type semiconductor layer 82″, and first and second electrodes 81a″ and 82a″.

The first electrode 81a″ maybe electrically connected to the first conductivity-type semiconductor layer 81″ through a via V passing through the active layer 83″ and the second conductivity-type semiconductor layer 82″. The second electrode 82a″ may be connected to the second conductivity-type semiconductor layer 82″.

An electrode insulating layer 85″ may be disposed around the via V in order to electrically insulate the first electrode 81a″ from the second conductivity-type semiconductor layer 82″ and from the active layer 83″. The electrode insulating layer 85′ may be interposed between the first electrode 81a′ and the second electrode 82a″, and include silicon oxide or silicon nitride.

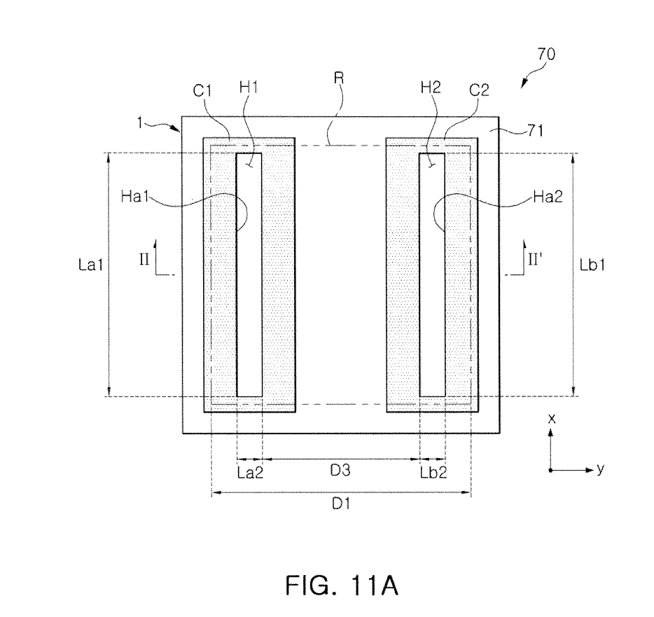

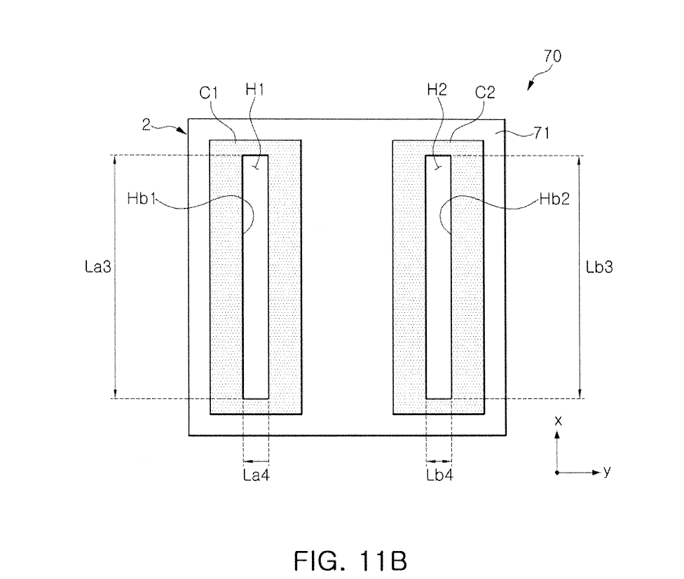

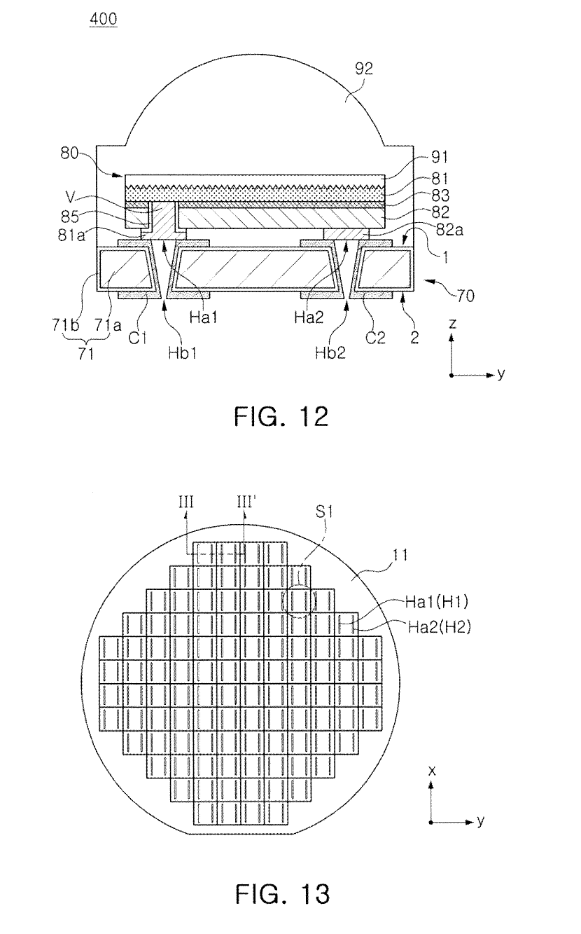

FIGS. 11A, 11B, and 12 illustrate an electronic device package 400 according to an exemplary embodiment in the present disclosure. More specifically, FIGS. 11A and 11B are respectively a top view and a bottom view of a package substrate 70 in the electronic device package 400 according to the exemplary embodiment in the present disclosure, and FIG. 12 is a cross-sectional view taken along line II-II′ of FIG. 11A.

Referring to FIGS. 11A, 11B, and 12, the electronic device package 400 according to the exemplary embodiment in the present disclosure includes a package substrate 70 and an electronic device 80. The package substrate 70 includes a package body 71 having a first surface 1 and a second surface 2 opposite to the first surface 1, and via-holes H1 and H2 passing through the package body 71 from the first surface 1 to the second surface 2. The package body 71 may include, but is not limited to, a body 71a and an insulating layer 71b.

Hereinafter, descriptions of the same parts as those in the embodiments described in FIGS. 1, 2A, 2B, and 3A are omitted, and the description will focus on those parts that are different from corresponding parts of the embodiments described above.

In this exemplary embodiment, at least one via-hole H1 and H2 may extend from the first surface 1 to the second surface 2, and may include first openings Ha1 and Ha2 and second openings Hb1 and Hb2. The first openings Ha1 and Ha2 may be formed on the first surface 1 of the package body 71. The first openings Ha1 and Ha2 may have first dimensions La1 and Lb1 and second dimensions La2 and Lb2. As illustrated in FIG. 11A, first dimensions La1 and Lb1 along a first direction x may be greater than second dimensions La2 and Lb2 in a second direction y substantially perpendicular to the first direction x.

The first openings Ha1 and Ha2 may have a rectangular shape on a surface of the package substrate 70 as illustrated in FIGS. 11A and 11B, but the shape of the openings is not limited thereto. For example, the first openings Ha1 and Ha2 may have an oval shape having a major axis or a minor axis.

The second openings Hb1 and Hb2 may be formed on the second surface 2 of the package body 71 at positions opposite to (and vertically aligned with) the first openings Ha1 and Ha2. The second openings Hb1 and Hb2 may have third dimensions La3 and Lb3 along the first direction x greater than fourth dimensions La4 and Lb4 in the second direction y substantially perpendicular to the first direction x, as illustrated in FIG. 11B.

The via-holes H1 and H2 having the first and second openings Ha1, Ha2, Hb1, and Hb2 may be formed using an etching process, such as dry etching and/or wet etching, or a laser drilling process.

The package substrate 70 may include conductive portions C1 and C2 extending along an inner sidewall of the via-holes H1 and H2. The conductive portions C1 and C2 may include an electrically conductive material, for example, a metal, such as Cu, Al, Au, Ag, Ni, and Pd. The conductive portions C1 and C2 may extend along the inner sidewall of the via-holes H1 and H2 and may be formed on portions of the first surface 1 and the second surface 2 of the package body 71 surrounding the via-holes H1 and H2.

For example, as illustrated in FIGS. 11A, 11B, and 12, when the package substrate 70 includes the first and second via-holes H1 and H2, the first and second conductive portions C1 and C2 may extend along the inner sidewall of the first and second via-holes H1 and H2 (please refer to FIG. 12). Here, the first and second conductive portions C1 and C2 are further respectively formed on portions of the first surface 1 of the package body 71 to be electrically connected to the first and second electrodes 81a and 82a of the electronic device 80 (please refer to FIGS. 11A and 12). In addition, since the first and second conductive portions C1 and C2 are formed on portions of the second surface 2 of the package body 71, the first and second conductive portions C1 and C2 may receive an external power from a bottom surface of the package body 71 and may transmit the external power to the electronic device 80 (please refer to FIGS. 11B and 12).

In this exemplary embodiment, the first openings Ha1 and Ha2 may be disposed in the mounting region R of the first surface 1 of the package body 71 defined as a region on which the electronic device 80 is disposed. For example, a distance D3 between the first openings Ha1 and Ha2 of the first and second via-holes H1 and H2 may be smaller than a horizontal length D1 of the mounting region R, that is, a horizontal size of the electronic device 80.

In this case, first and second conductive portions C1 and C2 respectively formed in the first and second via-holes H1 and H2 may be disposed on a portion overlapped by the electronic device 80 in a thickness direction, and heat generated from the electronic device package 400 maybe effectively released outwardly via the conductive portions C1 and C2.

That is, this exemplary embodiment may be understood as a modified form of the above-described exemplary embodiments described in relation to FIGS. 1, 2A, 2B, and 3A in which the conductive vias do not fully fill the via holes and instead extend along the inner sidewalls of the via holes.

FIGS. 13 to 15, 16A, 16B, and 17 to 21 are diagrams schematically illustrating main process steps involved in a method of fabricating an electronic device package according to an exemplary embodiment in the present disclosure. Here, although descriptions are described based on the electronic device package according to the exemplary embodiments of FIGS. 1, 2A, 2B, and 3A, the electronic device packages according to the exemplary embodiments of FIGS. 3B, 4, 5A, 5B, 6 to 10, 11A, 11B, and 12 may be also fabricated in a similar method. In addition, the manufacturing method described below is provided as an example of a manufacturing method that can be used to fabricate the electronic device package, and the electronic device package may also be fabricated using other manufacturing methods.

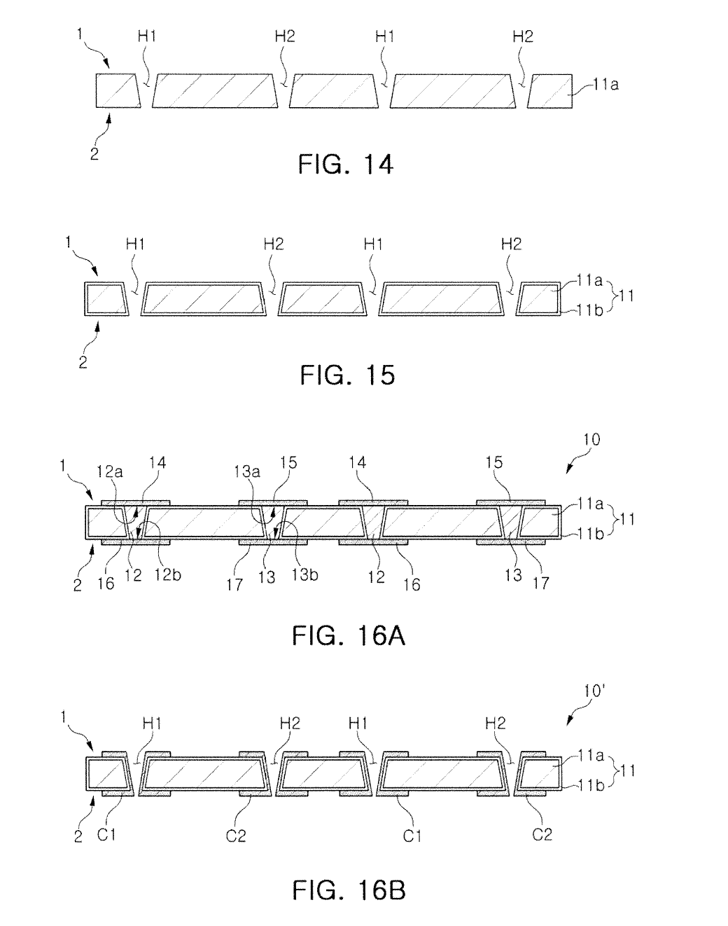

Referring to FIG. 14 along with FIG. 13, a body portion 11a of a package body 11 may be provided in the form of a wafer, and the body portion 11a may include a plurality of device regions to Si. Here, FIG. 14 is a cross-sectional view taken along line in FIG. 13.

The package body 11 may include a first surface 1 and a second surface 2, and one or more first and second via-holes H1 and H2 extending through the body portion 11a may be formed on each device region S1. The first and second via-holes H1 and H2 may be arranged in rows and columns on the wafer to form a regular pattern throughout the entire body portion 11a. The plurality of first and second via-holes H1 and H2 may be formed by an etching process and/or a drilling process. The first and second via-holes H1 and H2 may each include a first opening and a second opening formed on first and second surfaces 1 and 2 of the wafer, respectively. In this case, the first opening may have a first dimension in a first direction x greater than a second dimension in a second direction y substantially perpendicular to the first direction x. Similarly, the second opening may have a third dimension in the first direction x greater than a fourth dimension in the second direction y substantially perpendicular to the first direction x. The first opening maybe arranged in a mounting area of a device region (e.g., device region S1) defined as an area on which an electronic device is positioned in a process which will be described later.

The first and second via-holes H1 and H2 may have tapered cross-sections taken along a plane perpendicular to the first surface that increase from the first surface 1 toward the second surface 2, as illustrated in FIG. 14, but are not limited thereto. The first and second via-holes H1 and H2 may have tapered cross-sections taken along the plane perpendicular to the first surface that increase from the second surface 2 toward the first surface 1, or uniform cross-sections through the thickness of the body portion 11a from the first surface 1 to the second surface 2.

Referring to FIG. 15, an insulating layer 11b covering surfaces of the plurality of first and second via-holes H1 and H2 and a surface of the body portion 11a may be formed.

The insulating layer 11b may be formed, for example, by coating the body portion 11a with a resin having fluidity, and the coating process may include a screen printing process or a spin coating process.

Next, a conductive portion may be formed on the insulating layer 11b. The conductive portion may fully fill the first and second via-holes H1 and H2 as illustrated in FIG. 16A, and thereby a plurality of first and second conductive vias 12 and 13 may be formed. In this case, first and second ends 12a, 12b, 13a, and 13b of the first and second conductive vias 12 and 13 may have a first dimension in a first direction and a second dimension in a second direction, and the first dimension may be greater than second dimension.

Next, first and second electrode pads 14 and 15 may be disposed on the first surface 1 of the package body 11 (e.g., on the first ends 12a, 13a of the vias 12 and 13), and first and second external terminals 16 and 17 may be formed on the second surface 2 (e.g., on the second sends 12b, 13b of the vias 12 and 13). Thus, a package substrate 10 may be formed.

Meanwhile, the inventive concept is not limited thereto. As illustrated in FIG. 16B, conductive portions C1 and C2 may not fully fill the first and second via-holes H1 and H2, and may instead extend along inner walls of the first and second via-holes H1 and H2 and be disposed on portions of the first surface land the second surface 2 of the package body 11 (e.g., on portions of the first and second surfaces 1 and 2 surrounding the via-holes H1 and H2).

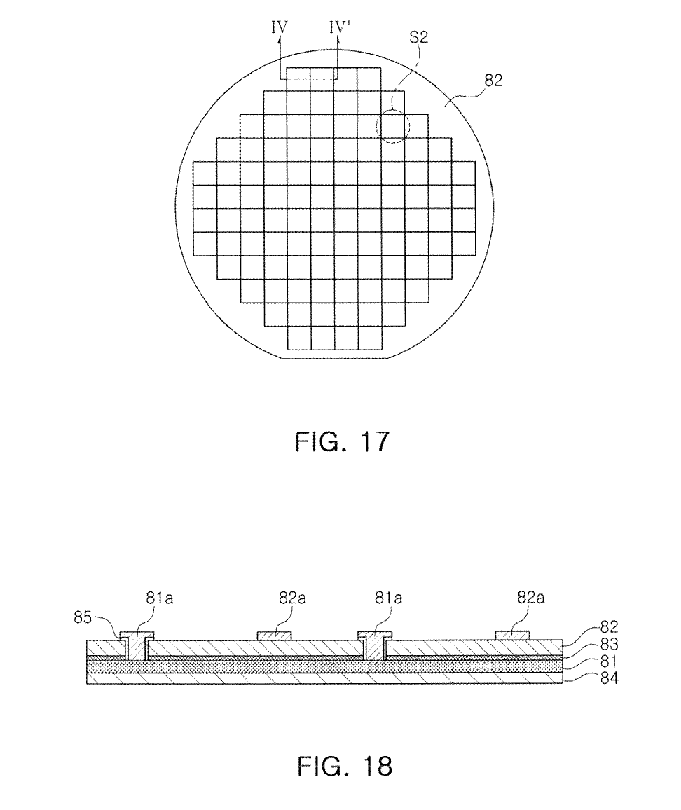

In FIGS. 17 and 18, a process of fabricating an electronic device 80 will be described. The electronic device 80 may be, but is not limited to, a semiconductor light-emitting device, for example. More specifically, referring to FIG. 17, a process of forming a light-emitting structure including a first conductivity-type semiconductor layer 81, an active layer 83, and a second conductivity-type semiconductor layer 82 on a substrate 84, may be performed.

FIG. 18 is a cross-sectional view taken along line IV-IV′ in FIG. 17.

Referring to FIG. 18 along with FIG. 17, the substrate 84 may be a wafer-level substrate, and device regions S2 configuring a plurality of electronic device 80 may be formed. One device region S2 may be understood as a chip region of one electronic device 80.

The substrate 84 may be a semiconductor growth substrate, for example, a Si substrate. A first conductivity-type semiconductor layer 81, an active layer 83, and a second conductivity-type semiconductor layer 82 may be sequentially grown on the substrate 84 using a well-known process in the art, such as a metal organic chemical vapor deposition (MOCVD) process, a hydride vapor phase epitaxy (HVPE) process, and a molecular beam epitaxy (MBE).

Next, in order to form a via V including a first electrode 81a, a through hole may be formed through the second conductivity-type semiconductor layer 82 and the active layer 83 by an etching process using a mask, and an electrode isolating layer 85 maybe deposited. However, the inventive concept is not limited thereto, a plurality of vias V may be formed on one device region.

Next, a conductive ohmic material may be formed on the light-emitting structure to form first and second electrodes 81a and 82a. For example, the first and second electrodes 81a and 82a may include various materials or have a stacked structure, to increase ohmic characteristics or reflective characteristics.

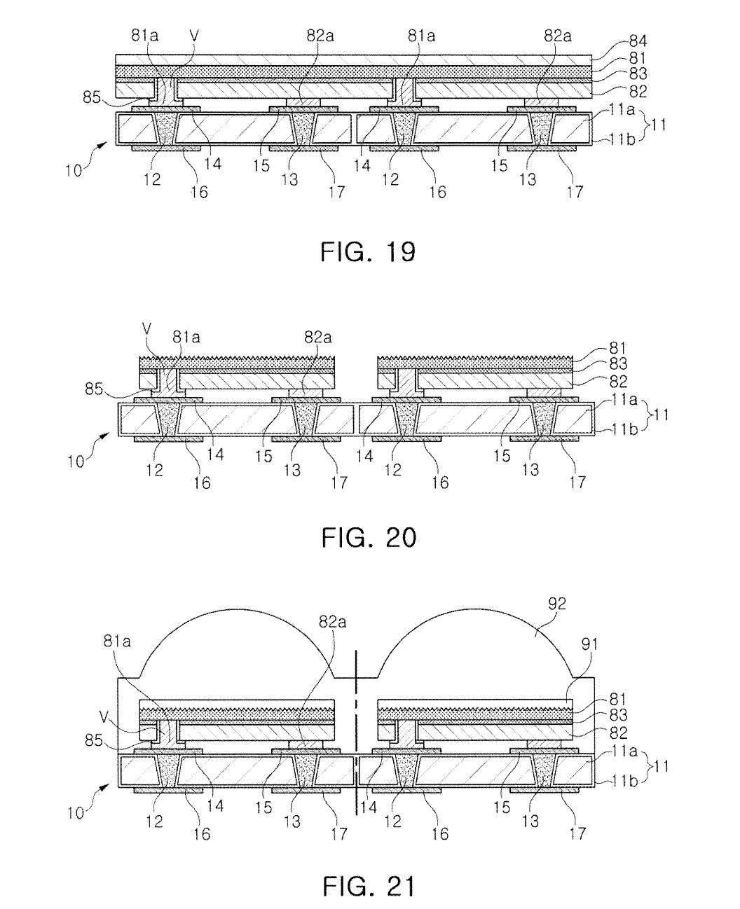

Referring to FIG. 19, a process of bonding the package substrate 10 described with reference to FIG. 16A to the substrate 84 including the light-emitting structure described with reference to FIG. 18 may be performed.

The bonding process may be performed to respectively connect the first and second electrode pads 14 and 15 of the package substrate 10 to the first and second electrodes 81a and 82a of the electronic device. The bonding process may include, for example, a eutectic bonding process. In some embodiments, an additional solder ball or an adhesive layer may be interposed between the first and second electrode pads 14 and 15 and the first and second electrodes 81a and 82a.

Referring to FIG. 20, first, the substrate 84 may be removed. The substrate 84 may be removed by a laser lift-off process when the substrate 84 is formed of a transparent material such as sapphire, or the substrate 84 may be removed by a mechanical grinding or polishing, or wet or dry etching when the substrate 84 is formed of silicon. In some embodiments, the substrate 84 may not be removed.

Next, a textured structure may be formed on an upper/exposed surface of the first conductivity-type semiconductor layer 81 in order to improve light extraction efficiency. When the substrate 84 is not removed, the textured structure may be formed on an upper surface of the substrate 84. The textured structure may be formed, for example, by mechanical cutting, grinding, wet etching, or dry etching using plasma.

Next, a process is performed for separating the light-emitting structure into units of the electronic device 80. Thus, a plurality of electronic devices 80 may be formed. Before the separation process is performed, a passivation layer covering at least a portion of the light-emitting structure may be formed. In addition, the textured structure on the first conductivity-type semiconductor layer 81 may be formed after the process of separating the light-emitting structure is performed. In this exemplary embodiment, first ends 12a and 13a of the first and second conductive vias 12 and 13 may be disposed on a mounting area defined as an area on which the electronic device 80 is positioned.

Referring to FIG. 21, a wavelength converting part 91 and a lens part 92 may be formed on the electronic device 80.

The wavelength converting part 91 may be formed of an oxide-based, silicate-based, nitride-based, or a sulfide-based fluorescent material mixture. In the case of the oxide-based material, (Y, Lu, Se, La, Gd, Sm)₃(Ga, Al)₅O₁₂:Ce as a yellow and green fluorescent material, BaMgAl₁₀O₁₇:Eu or 3Sr₃(PO₄)₂.CaCl:Eu as a blue fluorescent material, and the like may be used. In the case of the silicate-based material, (Ba, Sr)₂SiO₄:Eu as a yellow and green fluorescent material, (Ba, Sr)₃SiO₅:Eu as a yellow and orange fluorescent material, and the like maybe used. In addition, in the case of the nitride-based material, β-SiAlON:Eu as a green fluorescent material, (La, Gd, Lu, Y, Sc)₃Si₈N₁₁:Ce as a yellow fluorescent material, α-SiAlON:Eu as an orange fluorescent material, (Sr, Ca)AlSiN₃:Eu, (Sr, Ca)AlSi(ON)₃:Eu, (Sr, Ca)₂Si₅N₈:Eu, (Sr, Ca)₂Si₅(ON)₈:Eu, or (Sr, Ba)SiAl₄N₇:Eu as a red fluorescent material, and the like may be used, and in the case of the sulfide-based material, (Sr, Ca)S:Eu or (Y, Gd)₂O₂S:Eu as a red fluorescent material, SrGa₂S₄:Eu as a green fluorescent material, and the like may be used.

The lens part 92 may be formed on the wavelength converting part 91 by spray coating, for example. The lens part 92 may be formed by being applied on the electronic device 80 and the wavelength converting part 91 to have a predetermined shape and cured.

Next, an electronic device package 100 illustrated in FIGS. 1, 2A, 2B, and 3A may be formed by performing a separation process along the alternated long and short dash line of FIG. 21 to form individual electronic device package units. The separation process maybe performed by blade cutting or laser cutting. Thus, a large number of electronic device packages may be simultaneously fabricated. In particular, since a chip-scale package (CSP) according to the exemplary embodiment in the present disclosure does not include a reflective-cup shaped molding structure, the overall package size may correspond to a chip size. Accordingly, it is suitable for size reduction of a product.

Meanwhile, in the above-described manufacturing method, the light-emitting structure is described as being bonded to the package substrate in which the conductive via has been formed, but is not limited thereto.

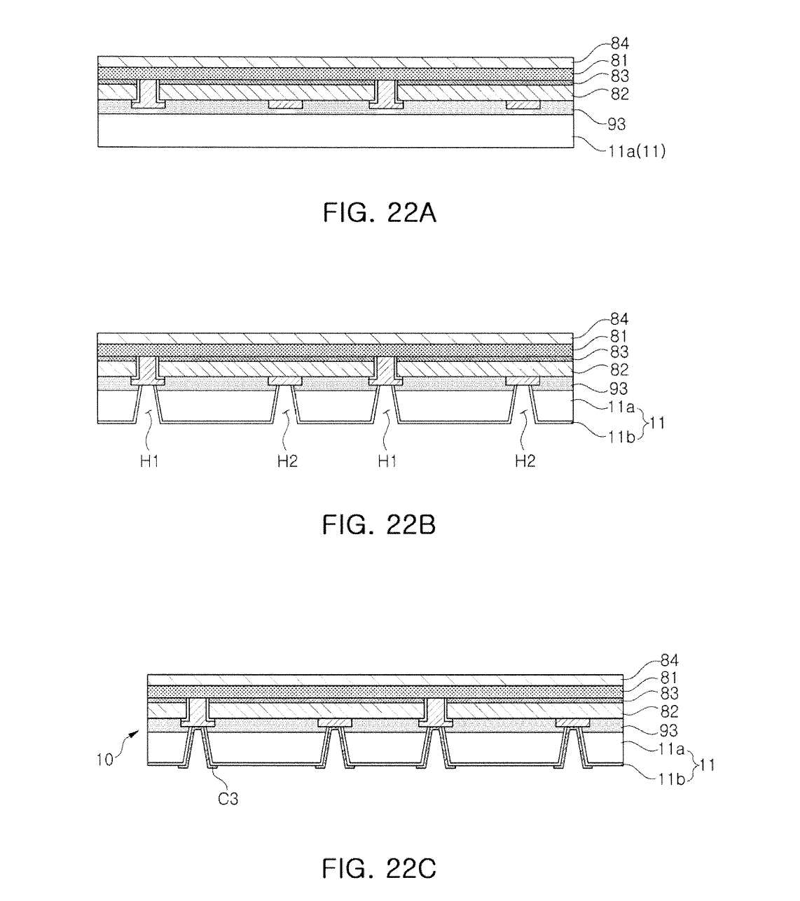

For example, as illustrated in FIG. 22A, first, the substrate 84 in which the light-emitting structure is formed and the package body 11 may be bonded. The package body 11 may be bonded to the light-emitting structure by an adhesive layer 93. Here, the package body 11 may be in a state in which a via hole and/or a conductive via are not formed. The adhesive layer 93 may be, but is not limited to being, formed of an electrically insulating material. As the electrically insulating material, an oxide such as SiO2 or SiN, or a resin material such as silicone resin or epoxy resin may be used.

Next, as illustrated in FIG. 22E, first and second via-holes H1 and H2 may be formed on the package body 11, and an insulating layer 11b covering inner walls of the first and second via-holes H1 and H2 and at least a portion of a surface of the body portion 11a may be formed. Each of the first and second via-holes H1 and H2 may include first and second openings, as described above. The first and second openings may have, for example, a rectangular shape or an elliptical shape and may be formed to extend through the package body 11 and adhesive layer 93 to electrodes formed on the second conductivity-type semiconductor layer 82.

Next, as illustrated in FIG. 22C, conductors C3 may be formed in the first and second via-holes H1 and H2. The conductors 03 are shown as extending along the inner walls of the first and second via-holes H1 and H2, but are not limited thereto. The conductors C3 may fully fill the first and second via-holes H1 and H2.

Next, similarly to the explanation described above with to reference to FIGS. 20 and 21, electronic device packages may be formed by separating the light-emitting structure into electronic device units, and the package substrate 10 into electronic device package units.

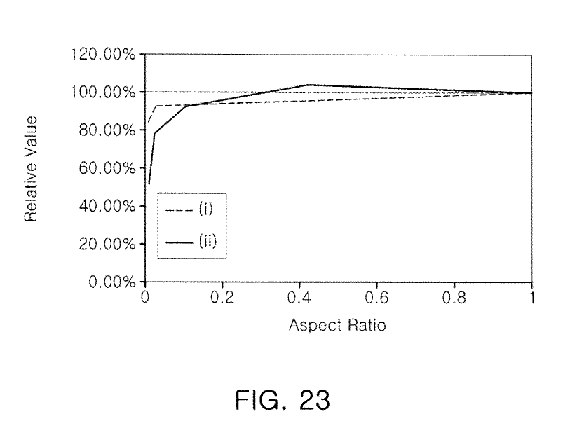

FIG. 23 is a comparative experimental graph for describing an effect of an electronic device package according to an exemplary embodiment in the present disclosure.

In this comparative experiment, a conductive via having a cylindrical shape as a whole, in which first and second ends have a circular shape with a constant radius of 35 μm, was used as first and second conductive vias of a comparative example. As an experimental embodiment, the rectangular first and second conductive vias illustrated in FIGS. 1, 2A, 2B, and 3A were used. More specifically, according to the experimental embodiment, while the rectangular first and second conductive vias had the same total volume as the cylindrical first and second conductive vias of the comparative example, an aspect ratio of the first and second ends (aspect ratio=a second dimension of the first end/a first dimension of the first end) of the rectangular first and second conductive vias according to the experimental embodiment was gradually reduced. As a result, it is found that the electronic device package including a rectangular conductive via having an aspect ratio less than 1 according to the experimental embodiment has a reduced thermal resistance of the conductive via (please refer to line i), compared by regarding a thermal resistance of the comparative example as a reference (100%), and a reduced stress due to thermal expansion of the semiconductor layer(GaN) configuring the electronic device (please refer to line ii), compared to an electronic device package having an aspect ratio of 1 according to the comparative example.

More specifically, when the second dimension of the first end was about 0.1 times the first dimension, a thermal resistance and a stress applied to the semiconductor layer configuring an electronic device was reduced by about 10%, as shown in FIG. 23. In general, improvements in thermal resistance and applied stress are obtained when the second dimension of the first end is less than or equal to about 0.3 times the first dimension, or less than or equal to about 0.2 times the first dimension, as shown in FIG. 23.

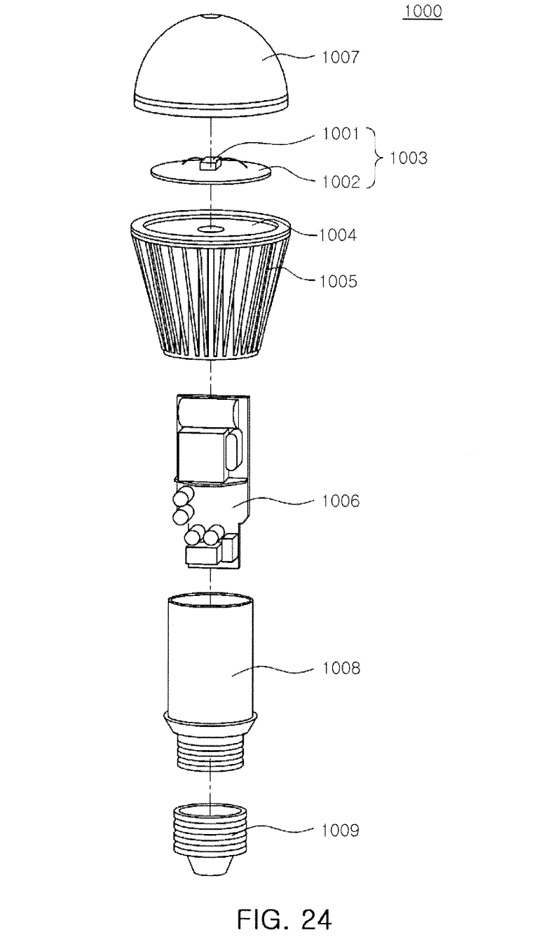

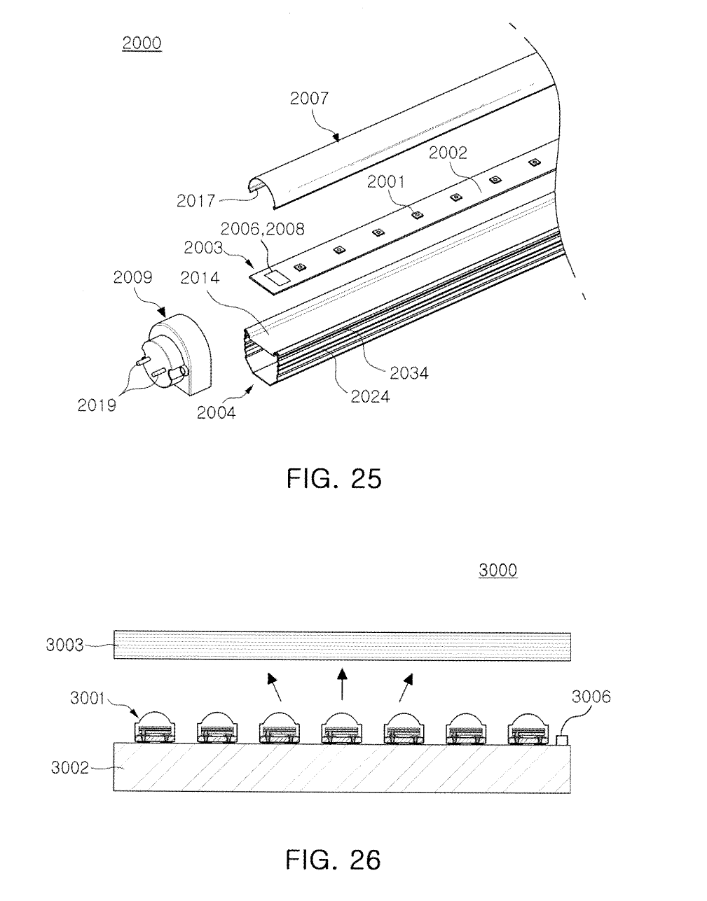

FIGS. 24 and 25 are exploded perspective views illustrating example apparatuses in which an electronic device package according to an exemplary embodiment in the present disclosure is applied as a light source of a lighting apparatus.

In these exemplary embodiments, the electronic device package may function as a light source. More specifically, the electronic device package may be a light-emitting device package including a semiconductor light-emitting device as an electronic device.

As illustrated in FIG. 24, a lighting apparatus 1000 according to an exemplary embodiment in the present disclosure may be a bulb-type lamp.

The lighting apparatus 1000 may have, but is not limited to, a similar shape to an incandescent lamp in order to replace the existing incandescent lamp, and may emit light having a similar optical characteristics (a color and a color temperature) to the incandescent lamp.

Referring to the exploded perspective view of FIG. 24, the lighting apparatus 1000 may include a light source unit 1003, a light source driving unit 1006, and an external connection unit 1009. In addition, external structures, such as external and internal housings 1005 and 1008 and a cover 1007, may be further included. The light source unit 1003 may include an electronic device package 1001 and a mounting board 1002 with the electronic device package 1001 mounted thereon. In the exemplary embodiment, a single electronic device package 1001 is mounted on the mounting board 1002, but a plurality of electronic device packages 1001 may be mounted as needed.

In addition, in the lighting apparatus 1000, the light source unit 1003 may include the external housing 1005 which functions as a heat dissipation unit, and the external housing 1005 may include a heat dissipation plate 1004 in direct contact with the light source unit 1003 to enhance a heat dissipation effect. Further, the lighting apparatus 1000 may include the cover 1007 installed on the light source unit 1003 and have a convex lens shape. The light source driving unit 1006 may be installed in the internal housing 1008 and may receive power from the external connection unit 1009, such as a socket structure. In addition, the light source driving unit 1006 may function to convert the power to an appropriate current source capable of driving the electronic device package 1001 of the light-emitting module 1003. For example, the light source driving unit 1006 may be configured as an AC-DC converter, a rectifying circuit component, or the like.

In addition, as illustrated in FIG. 25, a lighting apparatus 2000 according to an exemplary embodiment in the present disclosure may be a bar-type lamp. The lighting apparatus 2000 may have, but is not limited to, a similar shape to an incandescent lamp in order to replace the existing incandescent lamp, and may emit light having similar optical characteristics to the incandescent lamp.

Referring to the exploded perspective view of FIG. 25, a lighting apparatus 2000 may include a light source unit 2003, a body 2004, a terminal 2009, and a cover 2007 covering the light source unit 2003.

The light source unit 2003 may include a mounting board 2002, and a plurality of electronic device packages 2001 mounted on the mounting board 2002. A light source driving unit 2006 driving the electronic device packages 2001 of the light source unit 2003, and a controller 2008 controlling an operation of the light source driving unit 2006 may be disposed on the mounting board 2002.

The body 2004 may mount and fix the light source unit 2003 on a surface thereof. The body 2004 may be a kind of a supporting structure and include a heat sink. The body 2004 may be, but is not limited to being, formed of a material having a high thermal conductivity, for example, a metal material, in order to release heat generated in the light source unit 2003 to the outside.

The body 2004 may have a long rod shape as a whole corresponding to a shape of the mounting board 2002 of the light source unit 2003. A recess 2014 capable of accommodating the light source unit 2003 may be formed on the surface on which the light source unit 2003 is mounted.

A plurality of heat dissipating fins 2024 for heat dissipation may be formed to protrude on both outer side surfaces of the body 2004. In addition, fastening grooves 2034 extending in a longitudinal direction of the body 2004 may be formed on both ends of the outer side surface disposed on the recess 2014. The cover 2007, which will be described later, may be fastened to the fastening groove 2034.

Both ends of the body 2004 in a longitudinal direction may be open such that the body 2004 has a pipe structure in which both ends thereof are open. In this exemplary embodiment, both ends of the body 2004 are described as being open, but are not limited thereto. For example, only one end of the body 2004 may be open.

The terminal 2009 may be disposed on at least one open end of both ends of the body 2004 in the longitudinal direction to supply power to the light source unit 2003. In this exemplary embodiment, both ends of the body 2004 are open and the terminal 2009 is disposed on each end of the body 2004. However, the inventive concept is not limited thereto. For example, in a structure in which only one end of the body 2004 is open, the terminal 2009 may be disposed on the one end of the body 2004.

The terminal 2009 may be connected to both open ends of the body 2004 to cover the open ends. The terminal 2009 may further include an electrode pin 2019 protruding outside.

The cover 2007 may have a semi-circularly curved surface so that light is uniformly emitted to the outside overall. In addition, an overhanging 2017 engaged with the fastening groove 2034 of the body 2004 may be formed at a bottom of the cover 2007 combined with the body 2004 in a longitudinal direction of the cover 2007.

In this exemplary embodiment, the cover 2007 is illustrated as having a semi-circularly curved surface, but is not limited thereto. For example, the cover 2007 may have a flat rectangular shape or another polygonal shape. The shape of the cover 2007 may be variously modified depending on a design of a lighting apparatus which emits light.

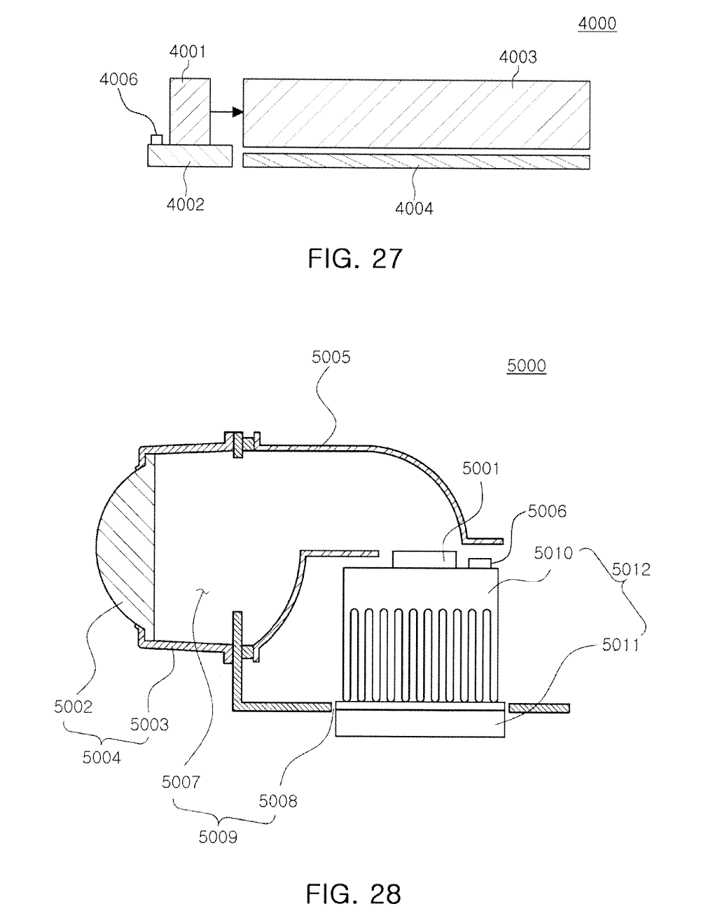

FIGS. 26 and 27 are cross-sectional views illustrating example units in which an electronic device package according to an exemplary embodiment in the present disclosure is applied as a light source of a backlight unit.

In this exemplary embodiment, the electronic device package may function as a light source. More specifically, the electronic device package may be a light-emitting device package including a semiconductor light-emitting device as an electronic device.

Referring to FIG. 26, a backlight unit 3000 may include a light source 3001 having an electronic device package and mounted on a mounting substrate 3002, and one or more optical sheet 3003 disposed on the light source 3001.

The light source 3001 in the backlight unit 3000 illustrated in FIG. 26 emits light toward a top surface where a liquid crystal display (LCD) is disposed. On the contrary, in another backlight unit 4000 illustrated in FIG. 27, a light source 4001 mounted on a mounting substrate 4002 emits light in a lateral direction, and the emitted light is incident to a light guide plate 4003 and converted to the form of surface light. Light passing through the light guide plate 4003 is emitted upwardly, and a reflective layer 4004 may be disposed on a bottom surface of the light guide plate 4003 to improve light extraction efficiency. The light sources 3001 and 4001 may include an electric device package having the above-described structure or a similar structure thereto.

The backlight units 3000 and 4000 illustrated in FIGS. 26 and 27 may include light source driving devices 3006 and 4006 supplying driving power to the light sources 3001 and 4001.

The light source driving devices 3006 and 4006 may include a light source driving unit and a controller, as described above.

FIG. 28 is a cross-sectional view illustrating an example in which an electronic device package according to an exemplary embodiment in the present disclosure is applied as a light source of a head lamp.

In this exemplary embodiment, the electronic device package may function as a light source. More specifically, the electronic device package may be a light-emitting device package including a semiconductor light-emitting device as an electronic device.

Referring to FIG. 28, a headlamp 5000 used as a vehicle lamp, or the like, may include a light source 5001, a reflective unit 5005, and a lens cover unit 5004. The lens cover unit 5004 may include a hollow-type guide 5003 and a lens 5002. In addition, the headlamp 5000 may further include a heat dissipation unit 5012 dissipating heat generated by the light source 5001 outwardly. In order to effectively dissipate heat, the heat dissipation unit 5012 may include a heat sink 5010 and a cooling fan 5011. In addition, the headlamp 5000 may further include a housing 5009 fixedly supporting the heat dissipation unit 5012 and the reflective unit 5005, and the housing 5009 may have a central hole 5008 formed in one surface thereof, to which the heat dissipation unit 5012 is coupled. Further, the housing 5009 may have a front hole 5007 formed on the other surface integrally connected to the one surface and bent in a right angle direction. Accordingly, a front side of the housing 5009 may be open by the reflective unit 5005. The reflective unit 5005 is fixed to the housing 5009 such that the opened front side corresponds to the front hole 5007, and thereby light reflected is by the reflective unit 5005 may pass through the front hole 5007 to be emitted outwardly. The light source 5001 may include at least one electronic device package.

In this embodiment, the headlamp may further include a light source driving device 5006 for driving the light source 5001. The light source driving device 5006 may include a light source driving unit and a controller, as described above.

According to the exemplary embodiments in the present disclosure, an electronic device package is designed to have reduced thermal stress and improved reliability.

While exemplary embodiments have been shown and described above, it will be apparent to those skilled in the art that modifications and variations could be made without departing from the scope of the present invention as defined by the appended claims.

What is claimed is:

1. An electronic device package, comprising:
a package body including a first surface and a second surface opposite to the first surface;
an electronic device disposed on the first surface; and
at least one conductive via extending through the package body and including a first end located in a mounting region of the first surface corresponding to a region on which the electronic device is disposed,
wherein the first end has a first dimension measured along a first direction greater than a second dimension measured along a second direction substantially perpendicular to the first direction.

2. The electronic device package of claim 1, wherein the second dimension of the first end is less than or equal to 0.1 times the first dimension.

3. The electronic device package of claim 1, wherein the second dimension of the first end is less than or equal to 0.3 times the first dimension.

4. The electronic device package of claim 1, wherein the electronic device includes a first electrode and a second electrode, and
the at least one conductive via includes a first conductive via and a second conductive via respectively electrically connected to the first electrode and the second electrode.

5. The electronic device package of claim 4, wherein the first direction of the first end of the first conductive via is the same as a first direction of a first end of the second conductive via.

6. The electronic device package of claim 4, wherein the first direction of the first end of the first conductive via is different from a first direction of a first end of the second conductive via.

7. The electronic device package of claim 4, further comprising a first electrode pad and a second electrode pad disposed on the first surface and respectively electrically connected to the first electrode and the second electrode.

8. The electronic device package of claim 4, wherein the at least one conductive via includes a plurality of first conductive vias located in the mounting region of the first surface and a plurality of second conductive vias located in the mounting region of the first surface.

9. The electronic device package of claim 8, wherein the first ends of the plurality of first conductive vias have different first dimensions.

10. The electronic device package of claim 9, wherein, among the plurality of first conductive vias, one first conductive via located adjacent to a central portion of the mounting region has a greater first dimension at the first end than another first conductive via located adjacent to an outer portion of the mounting region.

11. The electronic device package of claim 8, wherein the first ends of the plurality of first conductive vias have different first directions from each other.

12. The electronic device package of claim 1, wherein the first end of the at least one conductive via includes one edge and another edge opposite to the one edge in the first direction, and the one edge has a different length from a length of the other edge.

13. The electronic device package of claim 12, wherein the other edge is disposed closer to a periphery of the mounting region than the one edge, and the one edge is longer than the other edge.

14. The electronic device package of claim 1, wherein the at least one conductive via includes a second end located on the second surface of the package body opposite to the first surface, and has a tapered cross-section along a plane perpendicular to the first surface from the first end to the second end.

15. The electronic device package of claim 1, wherein the at least one conductive via includes a second end located on the second surface of the package body opposite to the first surface, and has a cross-sectional area along a plane parallel to the first surface that increases from the first end to the second end.

16. The electronic device package of claim 1, wherein the first end of the at least one conductive via extends outside of the mounting region on the first surface of the package body so as to extend in an area of the first surface that is not overlapped by the electronic device.

17. An electronic device package, comprising:
a package body including a first surface and a second surface opposite to the first surface;
an electronic device disposed on the first surface;
at least one via hole extending through the package body and including a first opening located in a mounting region of the first surface corresponding to a region on which the electronic device is disposed; and
a conductor extending along an inner sidewall of the at least one via hole and electrically connected to the electronic device,
wherein the first opening has a first dimension measured along a first direction greater than a second dimension measured along a second direction substantially perpendicular to the first direction.

18. The electronic device package of claim 17, wherein the conductor extends from the inner sidewall of the at least one via hole onto the first and second surfaces of the package body so as to cover portions of the first and second surfaces located adjacent to the at least one via hole.

19. A package substrate for mounting an electronic device having a plurality of electrodes, the package substrate comprising:
a package body having a first surface and a second surface opposite to the first surface;
a plurality of via holes extending from the first surface through the package body to the second surface; and
a plurality of via conductors each disposed in a corresponding via hole of the plurality of via holes,
wherein each via hole of the plurality of via holes has a first end located in a mounting region of the first surface corresponding to a region on which an electrode of the electronic device is mounted,
wherein the first end of each via hole has a first dimension measured along a first direction greater than a second dimension measured along a second direction substantially perpendicular to the first direction, and
wherein each via hole has a second end located in the second surface, and the second end of each via hole has a third dimension measured along the first direction greater than a fourth dimension measured along the second direction substantially perpendicular to the first direction.

20. The package substrate of claim 19, wherein the first end of each via hole is vertically aligned through a thickness of the package body with the second end of the via hole, and
wherein the first, second, third, and fourth dimensions are different from each other.
